(19) United States
(12) Patent Application Publication
(10) Pub. No.: US 2025/0047074 A1
(43) Pub. Date: Feb. 6, 2025

(54) SEMICONDUCTOR LASER AND DISPLAY DEVICE THEREOF

(71) Applicant: Xiamen San'an Optoelectronics Co., Ltd., Fujian (CN)

(72) Inventor: Yushou Wang, Fujian (CN)

(73) Assignee: Xiamen San'an Optoelectronics Co., Ltd., Fujian (CN)

(21) Appl. No.: 18/924,975

(22) Filed: Oct. 23, 2024

Related U.S. Application Data
(63) Continuation of application No. PCT/CN2022/089489, filed on Apr. 27, 2022.

(51) Int. Cl. H01S 5/30; H01S 5/20

(52) U.S. Cl. CPC H01S 5/3063; H01S 5/2009

(57) ABSTRACT

Provided is a semiconductor laser and a display device thereof. The semiconductor laser includes a first semiconductor layer, a second semiconductor layer, and an active layer located therebetween; a first waveguide layer is disposed between the first semiconductor layer and the active layer, and a second waveguide layer is disposed between the second semiconductor layer and the active layer; an electron blocking layer is disposed between the second waveguide layer and the second semiconductor layer; the electron blocking layer includes at least a part of a P-type doped layer on a side close to the second semiconductor layer, in which a composition of the P-type doped layer is greater than 1E19⁻³; and a P-type doping concentration of the side of the electron blocking layer close to the second semiconductor layer is higher than a P-type doping concentration of the electron blocking layer away from the second semiconductor layer.

### CROSS-REFERENCE TO RELATED APPLICATION

This application is a continuation of international application of PCT application serial no. PCT/CN2022/089489, filed on Apr. 27, 2022. The entirety of the above-mentioned patent application is hereby incorporated by reference herein and made a part of this specification.

### BACKGROUND

### Technical Field

The disclosure relates to the field of semiconductor-related technology, and particularly relates to a laser diode and a display device thereof.

### Description of Related Art

Group III nitrides, represented by gallium nitride, are direct-transition wide-bandgap semiconductor materials with a wide energy bandgap, which are ideal materials for fabricating lasers from the ultraviolet band to the green band. Gallium nitride-based blue-green lasers have the advantages such as small size, high integration, high brightness, and high resolution. The distribution of the optical field and the photon confinement capability are key factors affecting the performance of gallium nitride-based blue-green lasers.

In conventional gallium nitride-based blue-green lasers, the electron blocking layer plays a role in suppressing electron overflow while also facilitating hole injection, in which P-type doping, such as magnesium doping, serves as the primary P-type hole supply layer in the electron blocking layer.

However, the poor activation efficiency of magnesium results in a doping concentration too low to provide sufficient hole concentration, thereby affecting luminescence efficiency. Conversely, an excessively high doping concentration can lead to optical absorption, impacting the brightness of the laser. In addition, the device is affected by heat under prolonged operation, causing a trace amount of magnesium to diffuse into the active layer to form non-radiative recombination defects and lead to light decay.

### SUMMARY

In order to solve the above technical problems, the disclosure provides a semiconductor laser, primarily involving a blue-green laser, and the light emission wavelength of the laser is 430 nm to 550 nm. An electron blocking layer is disposed, the electron blocking layer includes aluminum gallium nitride and/or aluminum indium gallium nitride, the aluminum concentration in the electron blocking layer is varied, and the variation of aluminum concentration is utilized to restrict the diffusion of P-type doping, which mainly refers to restricting the diffusion of magnesium. The electron blocking layer includes a P-type doped layer on the side close to the second semiconductor layer, and the P-type doping concentration of the P-type doped layer is not less than 1E19 cm⁻³. The P-type doping concentration of the side of the electron blocking layer close to the second semiconductor layer is higher than the P-type doping concentration of the side of the electron blocking layer away from the second semiconductor layer, ensuring that P-type doping provides sufficient holes. Calculations indicate that in the photon confinement region, the high magnesium doping concentration in the electron blocking layer is the primary source of photon absorption. The P-type doping high concentration region is disposed away from the second waveguide layer to reduce the optical absorption of the second waveguide layer and enhance light extraction efficiency.

According to the disclosure, preferably, a high aluminum blocking layer is further included. The high aluminum blocking layer is disposed between the second waveguide layer and the electron blocking layer, and the aluminum component of the high aluminum blocking layer is more than twice of the electron blocking layer; or alternatively, disposed on the side of the electron blocking layer close to the second waveguide layer, and the aluminum component of the high aluminum blocking layer is more than twice of other regions in the electron blocking layer. The increased aluminum component is further utilized to restrict the diffusion of P-type doping from the electron blocking layer to the second waveguide layer. Preferably, the high aluminum blocking layer is a non-P-type doped layer.

According to the disclosure, preferably, in order to take into account facilitating the effect of hole injection while avoiding the restriction of hole movement caused by high aluminum, particularly the restriction of hole movement to the active layer, the composition of the high aluminum blocking layer includes In_{y}AlₓGa_{(1-x-y)}N, in which x is 0.5 to 1, y is 0 to 0.2, the thickness of the high aluminum blocking layer is not greater than 0.003 μm, and the instantaneous doping process is used to improve the internal quantum efficiency of the product.

According to the disclosure, preferably, the thickness of the P-type doped layer in the electron blocking layer is 0.001 μm to 0.01 μm, which enhances the diffusion inhibition effect.

According to the disclosure, preferably, the electron blocking layer has a first P-type doping concentration peak, the electron blocking layer has an aluminum concentration peak, and the peak value of the first P-type doping concentration peak is located on a side of the aluminum concentration peak of the electron blocking layer close to the second semiconductor layer. By utilizing delayed doping in relation to the aluminum concentration peak, the diffusion of P-type impurities is prevented. The doping concentration of the peak value of the first P-type doping concentration peak is not lower than the P-type doping concentrations of other regions in the electron blocking layer.

According to the disclosure, preferably, the electron blocking layer has a second P-type doping concentration peak, and the second P-type doping concentration peak is located between the first P-type doping concentration peak and the second waveguide layer. The second P-type doping concentration peak is affected by the position of the aluminum concentration peak, and the distance between the second P-type doping concentration peak and the aluminum concentration peak is less than 50 angstroms.

According to the disclosure, preferably, the electron blocking layer has a second P-type doping concentration peak, and the peak value of the second P-type doping concentration peak is located on a side of the peak value of the aluminum concentration peak of the electron blocking layer close to the second waveguide layer. The second P-type doping concentration peak serves as a buffer for the diffusion of P-type doping, further preventing the diffusion of P-type doping to the second waveguide layer.

According to the disclosure, preferably, the distance between the peak of the first P-type doping concentration and the second waveguide layer is 0.005 μm to 0.02 μm, the upper limit is to increase the hole injection efficiency, and the lower limit is to prevent the diffusion of Mg to the second waveguide layer. The distance between the peak value of the first P-type doping concentration and the surface of the electron blocking layer close to the second semiconductor layer is 0 μm to 0.01 μm.

According to the disclosure, preferably, the peak value of the first P-type doping concentration peak is higher than the peak value of the second P-type doping concentration peak, and the peak concentration of the second P-type doping concentration peak is not less than 1E19 cm⁻³. Doping is used to maximize the hole injection efficiency, while also considering the deceleration or buffering of doping diffusion.

According to the disclosure, preferably, the P-type doping concentration of the surface of the electron blocking layer close to the second waveguide layer is not less than 1E19 cm⁻³, and the high concentration P-type doping is used for deceleration or buffering of the P-type doping diffusion.

According to the disclosure, preferably, the P-type doping concentration of the second waveguide layer is not greater than 1E19 cm⁻³.

According to the disclosure, preferably, the electron blocking layer has a valley of P-type doping concentration, and the P-type doping concentration of the valley is lower than 70% of the maximum value of the P-type doping concentration in the electron blocking layer. The P-type doping concentration of the valley is less than 7E18 cm⁻³, and the actual doping setting may be less than 5E18 cm⁻³. The valley is used to restrict the diffusion of P-type doping.

The disclosure further provides a display device, including a display light source, in which the display light source adopts the semiconductor laser mentioned above.

The beneficial effects of the disclosure at least include: promoting the P-type doping high concentration region to be away from the second waveguide layer, reducing the optical absorption of the second waveguide layer, and controlling the P-type doping concentration of the second waveguide layer to be no greater than 1E19 cm⁻³. By using local doping technology to control the location of Mg doping at the end of the electron blocking layer, the same hole injection efficiency can be obtained and the P-type doping diffusion to the active layer can be slowed down.

### BRIEF DESCRIPTION OF THE DRAWINGS

In order to more clearly illustrate the technical solutions of the embodiments of the disclosure, the following provides a brief introduction to the drawings required for use in the embodiments. It should be understood that the following drawings only represent certain embodiments of the disclosure and should not be seen as limiting the scope. For ordinary technicians in this field, other related drawings may be obtained based on the drawings without requiring any inventive effort.

FIG. 1 is a schematic cross-sectional view of a laser diode according to Example 1 of the disclosure;

FIG. 2 is a component test data of the laser diode according to Example 1 of the disclosure;

FIG. 3 is a schematic cross-sectional view of a laser diode according to Example 2 of the disclosure;

FIG. 4 is a component test data of the laser diode according to Example 2 of the disclosure;

FIG. 5 is a cross-sectional photograph of the laser diode according to Example 2 of the disclosure;

FIG. 6 is a component test data of a laser diode according to Example 3 of the disclosure;

FIG. 7 is a diagram showing improvement in light efficiency according to Example 3 of the disclosure.

### DESCRIPTION OF THE EMBODIMENTS

The following describes the implementation methods of the disclosure through specific embodiments. Persons skilled in the art can easily understand other advantages and effects of the disclosure from the contents disclosed in this specification. The disclosure may also be implemented or operated through other different specific implementation methods, and the details in the disclosure may also be modified or changed in various ways based on different viewpoints and applications without departing from the spirit of the disclosure.

The composition of each layer included in the disclosure maybe analyzed by any suitable means, such as secondary ion mass spectrometry (SIMS); the thickness of each layer may be analyzed by any suitable method, such as transmission electron microscope (TEM) or scanning electron microscopy (SEM), to match the depth position of each layer on a SIMS map, for example.

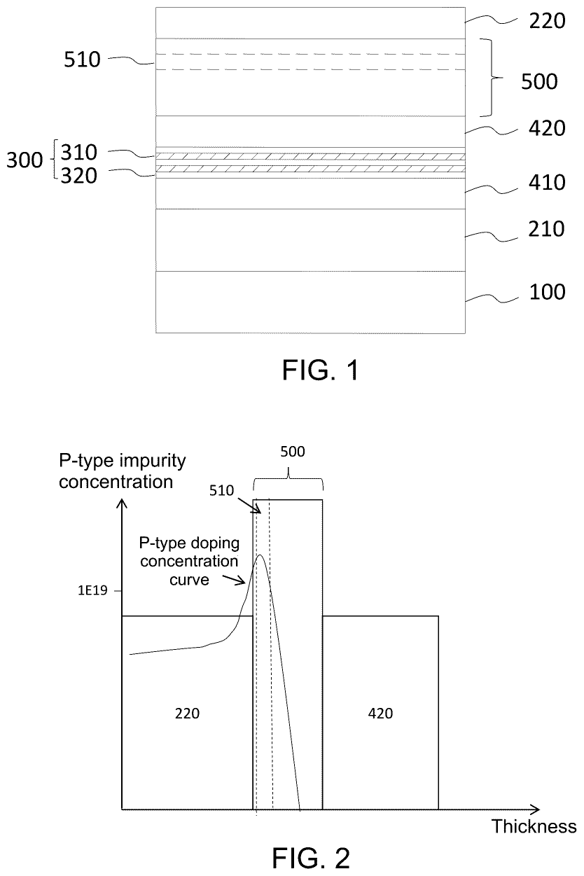

Referring to FIG. 1, in the first embodiment of the disclosure, a gallium nitride-based laser (i.e., semiconductor laser) and a laser diode are provided, including a substrate 100, in which the material of the substrate 100 includes but is not limited to gallium nitride, a first semiconductor layer 210 of N-type, a second semiconductor layer 220 of P-type, and an active layer 300 located therebetween are formed on the substrate 100; forming methods may include chemical vapor deposition; the active layer 300 is formed by a plurality of pairs of well layers 310 and barrier layers 320 periodically stacked; as an example, the material of the well layer 310 includes indium gallium nitride, the material of the barrier layer 320 includes gallium nitride, a first waveguide layer 410 is included between the first semiconductor layer 210 and the active layer 300, and a second waveguide layer 420 is included between the second semiconductor layer 220 and the active layer 300; the disclosure mainly involves lasers with an excitation wavelength in the range of 430 nm to 550 nm.

An electron blocking layer 500 is disposed between the second waveguide layer 420 and the second semiconductor layer 220. The material of the electron blocking layer 500 includes aluminum gallium nitride and/or aluminum indium gallium nitride, the electron blocking layer 500 restricts electrons from moving from the active layer 300 to the second semiconductor layer 220, thereby increasing the electron concentration in the active layer 300 and trapping the electrons in the active layer 300 to enhance recombination efficiency. The aluminum concentration in the electron blocking layer 500 is varied, and the concentration distribution of P-type doping is controlled by utilizing the varied aluminum concentration.

Specifically, the first waveguide layer 410 includes Alₓ₁In_{y1}Ga_{(1-x1-y1)}N, the value range of x1 is 0 to 0.1, and the value range of y1 is 0 to 0.2. The concentration of aluminum in the first waveguide layer 410 is preferably 3×10¹⁶ to 5×10¹⁷ cm⁻³, the concentration of indium is preferably 2×10²⁰ to 4×10²⁰ cm⁻³, and the refractive index of the first waveguide layer 410 is preferably 2.4 to 2.6. By doping a trace amount of aluminum component into the first waveguide layer 410, the lattice constant of the first waveguide layer 410 can be effectively reduced to match the first semiconductor layer 210. The material of the second waveguide layer 420 includes aluminum indium gallium nitride or indium gallium nitride, including Alₓ₂In_{y2}Ga_{(1-x2-y2)}N, in which the value range of x2 is 0 to 0.1, and the value range of y2 is 0 to 0.2. The concentration of aluminum in the second waveguide layer 420 is preferably 3×10¹⁶ to 5×10¹⁷ cm⁻³, and the concentration of indium is preferably 2×10²⁰ to 4×10²⁰ cm⁻³. The first waveguide layer 410 and the second waveguide layer 420 function as photon confinement capabilities.

Referring to FIG. 2 together, the electron blocking layer 500 includes a P-type doped layer 510 on a side close to the second semiconductor layer 220, and a composition of the P-type doped layer 510 is greater than 1E19 cm⁻³. The P-type doped layer 510 may be disposed on an end surface of the electron blocking layer 500 or disposed inside the electron blocking layer 500. The P-type doping concentration of a side of the electron blocking layer 500 close to the second semiconductor layer 220 is higher than the P-type doping concentration of a side of the electron blocking layer 500 away from the second semiconductor layer 220. In the disclosure, the electron blocking layer 500 to the second semiconductor layer 220 all adopt P-type doping. In this embodiment, the doping concentration of the P-type doped layer 510 is not lower than other regions of the second semiconductor layer 220 and the electron blocking layer 500. The distance between the P-type doped layer 510 and the well layer 310 on a side of the active layer 300 closest to the second semiconductor layer 220 is 0.2 μm to 0.3 μm. Compared to conventional designs, the high concentration region of P-type doping is increased away from the well layer 310, thereby enhancing the aging life of the product.

The P-type doped layer 510 is located at an end portion of the electron blocking layer 500 close to the second semiconductor layer 220. In this embodiment, the doping component in the P-type doped layer 510 is Mg doping. The thickness of the P-type doped layer in the electron blocking layer 500 is 0.001 μm to 0.01 μm. The total thickness of the electron blocking layer 500 is 0.003 μm to 0.05 μm.

In this embodiment, through process control, the P-type doping concentration of a surface of the electron blocking layer 500 close to the second waveguide layer 420 is set to be no greater than 1E19 cm⁻³. Meanwhile, the P-type doping concentration of the second waveguide layer 420 is not greater than 1E19 cm⁻³, so as to avoid aggravating the light absorption problem and reducing the photoelectric conversion efficiency due to high P-type doping concentration in the second waveguide layer 420.

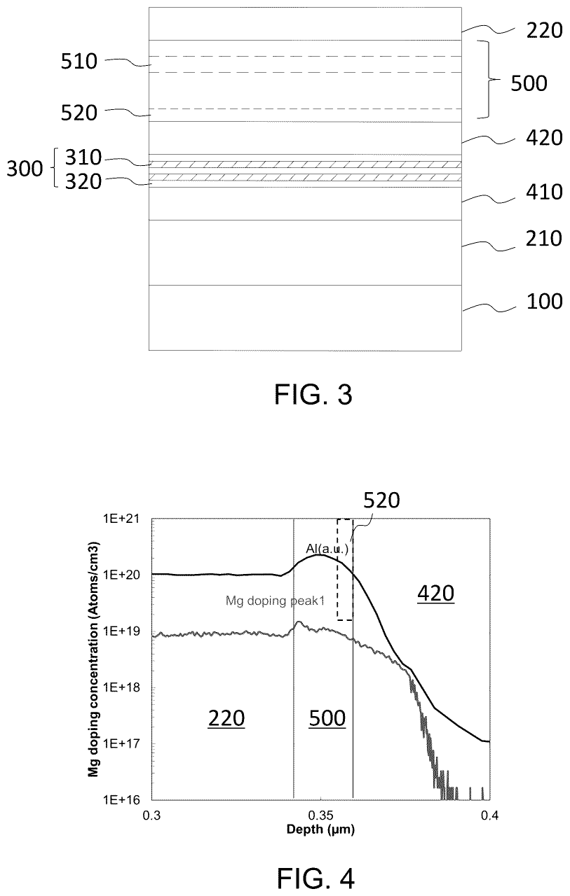

Referring to FIG. 3, in the second embodiment of the disclosure, a laser diode is provided. The difference from the first embodiment is that the epitaxial stack further includes a high aluminum blocking layer 520. In this embodiment, the high aluminum blocking layer 520 adopts non-P-type doping, and the high aluminum blocking layer 520 is disposed between the second waveguide layer 420 and the electron blocking layer 500. The aluminum component of the high aluminum blocking layer 520 is more than twice of the electron blocking layer 500. Alternatively, the high aluminum blocking layer 520 is disposed on a side of the electron blocking layer 500 close to the second waveguide layer 420, and the aluminum component of the high aluminum blocking layer 520 is more than twice of other regions in the electron blocking layer 500. The high aluminum blocking layer 520 is disposed to control the distribution of the aluminum component in the electron blocking layer 500, which includes not only the overlapping state of contacting each other, but also the state of overlapping with another layer inserted therebetween. Preferably, since the high aluminum blocking layer 520 is closer to the second waveguide layer 420 than other regions of the electron blocking layer 500, the high aluminum blocking layer 520 is configured as unintentional P-type doping. The distribution of aluminum content in the high aluminum blocking layer is not continuous, but is implemented by significantly increasing the aluminum component in a small range. Therefore, it is difficult to distinguish from the aluminum component of the electron blocking layer 500 using SIMS. However, a bright layer may appear in the TEM images.

The high aluminum blocking layer 520 of the disclosure includes In_{y}AlₓGa_{(1-x-y)}N, in which x is 0.5 to 1, y is 0 to 0.2, the thickness of the high aluminum blocking layer 520 is not greater than 0.003 μm, and the distribution of aluminum components is strictly controlled, which is beneficial to improving the efficiency of the P-type second semiconductor layer 220 injecting holes into the active layer 300.

Referring to FIG. 4, by disposing the high aluminum blocking layer 520, a first P-type doping concentration peak (Mg doping peak 1) is further formed in the electron blocking layer 500. The electron blocking layer 500 has an aluminum concentration peak, the peak value of the first P-type doping concentration peak is located on a side of a peak value of the aluminum concentration peak of the electron blocking layer 500 close to the second semiconductor layer 220, and the doping concentration of the peak value of the first P-type doping concentration peak is not lower than P-type doping concentrations of other regions in the electron blocking layer 500.

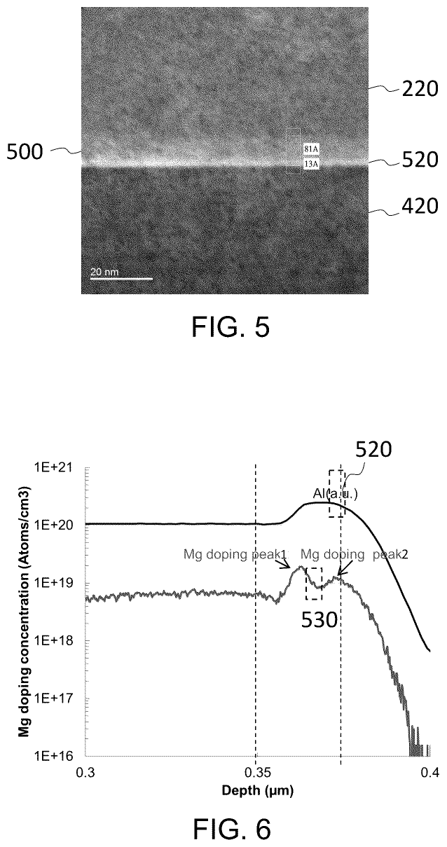

Referring to FIG. 5, a portion of the structure of the semiconductor layer sequence may be seen from detection using the transmission electron microscope, which mainly involves the second waveguide layer 420, the high aluminum blocking layer 520, the electron blocking layer 500, and the second semiconductor layer 220 from bottom to top, and the high aluminum blocking layer 520 has a higher brightness than other portions of the electron blocking layer 520. The high aluminum blocking layer 520 is located on the side of the electron blocking layer 500 close to the second waveguide layer 420. In some embodiments, the thickness of the electron blocking layer 500 is 94 angstroms, and the high aluminum blocking layer 520 is brighter and whiter than other portions of the electron blocking layer 500.

Referring to FIG. 6, in the third embodiment of the disclosure, a second P-type doping concentration peak is provided in the electron blocking layer 500, and the second P-type doping concentration peak is located between the first P-type doping concentration peak and the second waveguide layer 420. The electron blocking layer 500 has a second P-type doping concentration peak (Mg doping peak 2). The peak value of the second P-type doping concentration peak is located on a side of the peak value of the aluminum concentration peak of the electron blocking layer 500 close to the second waveguide layer 420.

The distance between the peak value of the first P-type doping concentration and the second waveguide layer 420 is not less than 0.005 μm, and the distance between the peak value of the first P-type doping concentration and a surface of the electron blocking layer 500 close to the second semiconductor layer 220 is 0 μm to 0.01 μm.

The peak value of the first P-type doping concentration peak is higher than the peak value of the second P-type doping concentration peak, and the peak concentration of the second P-type doping concentration peak is not less than 1E19 cm⁻³. The position of the second P-type doping concentration peak is controlled by controlling the first P-type doping concentration during the process and the high aluminum blocking layer.

In some implementations of this embodiment, a valley 530 of the P-type doping concentration is set in the electron blocking layer 500. The electron blocking layer 500 has the valley 530 of the P-type doping concentration, and the P-type doping concentration of the valley 530 is lower than 70% of the maximum value of the P-type doping concentration in the electron blocking layer 500. The P-type doping concentration of the valley 530 is less than 7E18, and the actual doping setting may be less than 5E18. The valley 530 is used to restrict the diffusion of P-type doping. However, due to the diffusion of the P-type doping concentration, only a distinct valley region can be observed in SIMS detection.

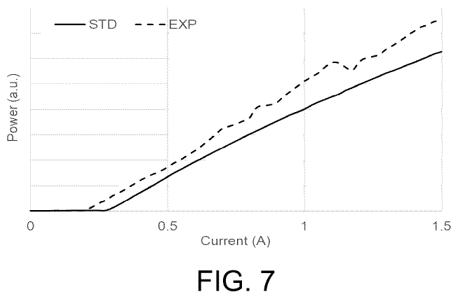

Referring to FIG. 7, in this embodiment, the solution can significantly reduce the absorption of P-type doping in the second waveguide layer 420 after implementation, further enhancing the slope after lasing and increasing the brightness. For example, at a current of 1.5 amperes, the product brightness is increased by 20%.

In the fourth embodiment of the disclosure, a display device is provided, including a display light source, in which the display light source is any semiconductor laser in the above embodiments.

The above is only preferred implementations of the disclosure. It should be noted that for ordinary technicians in this technical field, several improvements and substitutions may be made without departing from the technical principles of the disclosure. The improvements and substitutions should also be regarded as within the scope of protection of the disclosure.

What is claimed is:

1. A semiconductor laser, comprising a first semiconductor layer of N-type, a second semiconductor layer of P-type, and an active layer located between the first semiconductor layer and the second semiconductor layer and configured to emit light, wherein a first waveguide layer is disposed between the first semiconductor layer and the active layer, and a second waveguide layer is disposed between the second semiconductor layer and the active layer, wherein
an electron blocking layer is disposed between the second waveguide layer and the second semiconductor layer,
a material of the electron blocking layer comprises aluminum gallium nitride and/or aluminum indium gallium nitride, wherein
the electron blocking layer comprises a P-type doped layer on a side close to the second semiconductor layer, and a P-type doping concentration of a side of the electron blocking layer close to the second semiconductor layer is higher than a P-type doping concentration of a side of the electron blocking layer away from the second semiconductor layer.

2. The semiconductor laser according to claim 1, wherein the P-type doped layer is located at an end portion of the electron blocking layer close to the second semiconductor layer, and a doping component in the P-type doped layer is Mg doping.

3. The semiconductor laser according to claim 1, further comprising a high aluminum blocking layer, wherein the high aluminum blocking layer is disposed between the second waveguide layer and the electron blocking layer, and an aluminum component of the high aluminum blocking layer is more than twice of the electron blocking layer, or alternatively, the high aluminum blocking layer is disposed on a side of the electron blocking layer close to the second waveguide layer, and the aluminum component of the high aluminum blocking layer is more than twice of other regions in the electron blocking layer.

4. The semiconductor laser according to claim 3, wherein a composition of the high aluminum blocking layer comprises In_{y}AlₓGa_{(1-x-y)}N, x is 0.5 to 1, y is 0 to 0.2, and a thickness of the high aluminum blocking layer is not greater than 0.003 μm.

5. The semiconductor laser according to claim 1, wherein a thickness of the P-type doped layer in the electron blocking layer is 0.001 μm to 0.01 μm.

6. The semiconductor laser according to claim 1, wherein the electron blocking layer has a first P-type doping concentration peak, the electron blocking layer has an aluminum concentration peak, a peak value of the first P-type doping concentration peak is located on a side of a peak value of the aluminum concentration peak of the electron blocking layer close to the second semiconductor layer, and a doping concentration of the peak value of the first P-type doping concentration peak is not lower than P-type doping concentrations of other regions in the electron blocking layer.

7. The semiconductor laser according to claim 6, wherein the electron blocking layer has a second P-type doping concentration peak, and a peak value of the second P-type doping concentration peak is located between the first P-type doping concentration peak and the second waveguide layer.

8. The semiconductor laser according to claim 6, wherein the electron blocking layer has a second P-type doping concentration peak, and a peak value of the second P-type doping concentration peak is located on a side of the peak value of the aluminum concentration peak of the electron blocking layer close to the second waveguide layer.

9. The semiconductor laser according to claim 6, wherein a distance between the peak value of the first P-type doping concentration peak and the second waveguide layer is 0.005 μm to 0.02 μm, and a distance between the peak value of the first P-type doping concentration and a surface of the electron blocking layer close to the second semiconductor layer is 0 μm to 0.01 μm.

10. The semiconductor laser according to claim 7, wherein the peak value of the first P-type doping concentration peak is higher than the peak value of the second P-type doping concentration peak, and a peak concentration of the second P-type doping concentration peak is not less than 1E19 cm⁻³.

11. The semiconductor laser according to claim 7, wherein a distance between the second P-type doping concentration peak and the aluminum concentration peak is less than 50 angstroms.

12. The semiconductor laser according to claim 1, wherein a P-type doping concentration of a surface of the electron blocking layer close to the second waveguide layer is not less than 1E19 cm³.

13. The semiconductor laser according to claim 1, wherein a material of the second waveguide layer comprises aluminum indium gallium nitride or indium gallium nitride, and a P-type doping concentration of the second waveguide layer is not greater than 1E19 cm⁻³.

14. The semiconductor laser according to claim 1, wherein a P-type doping concentration of the P-type doped layer is not less than 1E19 cm⁻³.

15. The semiconductor laser according to claim 1, wherein a total thickness of the electron blocking layer is 0.003 μm to 0.05 μm.

16. The semiconductor laser according to claim 1, wherein the semiconductor laser is gallium nitride-based and a wavelength of an emitted light is 430 nm to 550 nm.

17. The semiconductor laser according to claim 3, wherein the high aluminum blocking layer is unintentional P-type doping.

18. The semiconductor laser according to claim 1, wherein the active layer is formed by periodically stacking a plurality of pairs of well layers and barrier layers, and a distance between the P-type doped layer and a well layer on a side of the active layer closest to the second semiconductor layer is 0.2 μm to 0.3 μm.

19. The semiconductor laser according to claim 1, wherein the electron blocking layer has a valley of the P-type doping concentration, and the P-type doping concentration of the valley is lower than 70% of a maximum value of the P-type doping concentration in the electron blocking layer.

20. A display device, comprising a display light source, wherein the display light source is the semiconductor laser according to claim 1.
